(19) United States
(12) Patent Application Publication
(10) Pub. No.: US 2013/0002274 A1
(43) Pub. Date: Jan. 3, 2013

(54) AGING DEGRADATION DIAGNOSIS CIRCUIT AND AGING DEGRADATION DIAGNOSIS METHOD FOR SEMICONDUCTOR INTEGRATED CIRCUIT

(75) Inventors: Eisuke Saneyoshi, Tokyo (JP); Koichi Nose, Tokyo (JP)

(73) Assignee: NEC Corporation, Tokyo (JP)

(21) Appl. No.: 13/634,188

(22) PCT Filed: Mar. 11, 2011
(86) PCT No.: PCT/JP2011/056495

§ 371 Date: Sep. 11, 2012

(30) Foreign Application Priority Data
Mar. 29, 2010 (JP) 2010-075292

(51) Int. Cl. G01R 31/26

(52) U.S. Cl. 324/750.01

(57) ABSTRACT

Provided is an aging degradation diagnosis circuit, including: a first delay circuit including a gate array for allowing aging degradation to progress, the first delay circuit being configured to delay an input signal and output a first output signal; a second delay circuit including a gate array having the same number of stages as the first delay circuit, the second delay circuit being configured to delay an input signal and output a second output signal; and an arbitrary delay unit, which is capable of varying a delay period in the second delay circuit by a predetermined amount. A delay comparison unit outputs comparison information obtained by relatively comparing delays between the first output signal and the second output signal. An adjustment unit uses the comparison information, to thereby readjust the delay period in the second delay circuit.

### TECHNICAL FIELD

This invention relates to an aging degradation diagnosis circuit for a semiconductor integrated circuit and a diagnosis method using the aging degradation diagnosis circuit.

### BACKGROUND ART

The performance of a semiconductor chip degrades with use after shipment (aging degradation), and when the degradation in performance has progressed to a certain extent, the semiconductor chip becomes defective. However, in the case where a semiconductor chip is determined to be defective in maintenance or the like, it is difficult to find out which of the end of the life (adequate decrease in performance due to aging degradation) or an accidental failure, etc., is responsible for.

In order to specify the true cause of a defect, it is therefore significantly important to enable diagnosis of the degree of progress of the degradation in performance of the semiconductor ship after shipment. This is because, if an unexpected failure or larger performance degradation than expected has been observed in diagnosis, feedback to design can be easily performed. Further, it becomes also possible to predict appropriate replacement timing in advance by acquiring log information on the degree of progress of the degradation in performance, which provides help in setting appropriate maintenance timing as well.

In the case of using an aging degradation diagnosis circuit for the above-mentioned purpose, it is desired to output and save degradation degree information without using an external measurement device. As a commonly-used method, there is employed a method in which a ring oscillator is configured in a semiconductor integrated circuit with the use of a C-MOS circuit, and the change in oscillation frequency is measured to calculate the degree of degradation. The oscillation frequency can be digitally encoded with the use of a counter, and hence the diagnosis of the degree of degradation can be performed with a simple circuit configuration without using an external measurement device.

In Non Patent Literature 1, two ring oscillators are used to improve the resolution of the degree of degradation in a practical range and thereby shorten a measurement time period.

Examples of the related art include Patent Literatures 1 and 2.

In an electrical property management method described in Patent Literature 1, a semiconductor device has an aging degradation diagnosis circuit provided therein. The aging degradation diagnosis circuit is provided with a degradation check circuit having the same laminate structure as that of an actual circuit element, a circuit for applying a high load to the degradation check circuit, and a sensor for measuring a degradation progress state. A higher load than the actual circuit element is applied to the degradation check circuit all the time, and the degradation thereof is monitored. In this manner, the replacement timing or the like of an actual circuit can be identified.

In a degradation diagnosis method described in Patent Literature 2, a semiconductor device has an aging degradation diagnosis circuit provided therein. The aging degradation diagnosis circuit includes a degradation diagnosis target circuit that is provided at the same timing as that of an actual circuit and allows a pulse signal (test signal) to pass therethrough. A signal obtained by delaying the test signal by a predetermined period is generated. The timing of the test signal having passed through the degradation diagnosis target circuit and the timing of a pulse are compared with each other. Based on a delay period thereof, degradation diagnosis is performed.

The aging degradation diagnosis circuit can be used in, for example, a semiconductor device described in Patent Literature 3.

### PRIOR ART LITERATURES

Patent Literature 1: Japanese Unexamined Patent Application Publication (JP-A) No. Hei 7-128384
Patent Literature 2: Japanese Unexamined Patent Application Publication (JP-A) No. 2008-147245
Patent Literature 3: Japanese Unexamined Patent Application Publication (JP-A) No. 2004-340877
Non Patent Literature 1: Tae-Hyoung Kim, Randy Persaud, and Chris H. Kim, “Silicon Odometer: An On-Chip Reliability Monitor for Measuring Frequency Degradation of Digital Circuits”, IEEE JOURNAL OF SOLID-STATE CIRCUITS, VOL. 43, NO. 4, pp. 874-880, APRIL, 2008

### SUMMARY OF INVENTION

### Problem to be Solved by the Invention

In the electrical property management method described in Patent Literature 1, degradation diagnosis is performed while applying a high load to the degradation check circuit. According to this method, the replacement timing or the like is estimated based on the accumulated degradation of the degradation check circuit, and hence the degradation check circuit itself needs to have the same structure as that of an actual circuit. In Patent Literature 2, the above-mentioned configuration is employed in view of the problems of physical scale and logical scale of the aging degradation diagnosis circuit.

On the other hand, in the electrical property management method described in Patent Literature 1, for example, in the case where a degradation diagnosis element is set as a temperature change, a fluctuating clock signal, an operating voltage, or the like, if the diagnosis is performed while applying a high load thereto, the life is underestimated or overestimated because of the deviation between a high load ratio and the operational state of an actual circuit.

Similarly, also in the aging degradation diagnosis method described in Patent Literature 2, no countermeasures are taken for the cause that affects degradation, such as the temperature change, the fluctuating clock signal, and the operating voltage, and hence an error occurs in an aging degradation diagnosis result depending on the operational state of the actual circuit.

Similarly, in the method of determining the degree of degradation by using the change in oscillation frequency of the ring oscillator described in Non Patent Literature 1, there is a problem that the oscillation frequency to be measured significantly fluctuates by the influence of environments (such as chip temperature and fluctuations in power supply voltage). In Non Patent Literature 1, this problem is somewhat alleviated by measuring the ratio of the oscillation frequencies with the use of two ring oscillators. However, it is necessary to produce a difference frequency signal of the two ring oscillators for measurement, and the period for producing the signal is affected by the environmental fluctuations.

Of various kinds of aging degradation, the degradation in performance by negative bias temperature instability (NBTI) is known to recover its degradation when a stress is removed. However, the details of the mechanism of the degradation recovery have not been revealed, and it is desired to perform the diagnosis of the degree of degradation in a state in which the influence of the recovery is removed as much as possible. Therefore, it is preferred that a measurement time period necessary to acquire a value for estimating degradation by the aging degradation diagnosis circuit be as short as possible.

This invention provides an aging degradation diagnosis circuit and an aging degradation diagnosis method for a semiconductor integrated circuit, which are capable of performing measurement in a short period of time with a simple circuit configuration while canceling an influence caused under measurement conditions.

### Means to Solve the Problem

An aging degradation diagnosis circuit according to an aspect of this invention is built in a semiconductor integrated circuit, and includes: a first delay circuit including a gate array having a predetermined number of stages for allowing aging degradation to progress, the first delay circuit being configured to delay an input signal by a delay period involved in the gate array and output a first output signal; a second delay circuit including a gate array having the same number of stages as the first delay circuit, the second delay circuit being configured to delay an input signal by a delay period involved in the gate array and output a second output signal; an arbitrary delay unit, which is capable of varying the delay period in the second delay circuit by a predetermined amount; a delay comparison unit, which receives the first output signal and the second output signal with respect to the same input signal to the first delay circuit and the second delay circuit, and outputs, as comparison information, a result of relatively comparing delays between the acquired first output signal and the acquired second output signal; and an adjustment unit for controlling the arbitrary delay unit with use of the comparison information from the delay comparison unit, to thereby readjust the delay period in the second delay circuit. With this configuration, degradation can be diagnosed based on the delay period provided to the second delay circuit.

An aging degradation diagnosis method for a semiconductor integrated circuit according to another aspect of this invention includes: relatively comparing, in a delay comparison step, a delay of a first output signal obtained by allowing a predetermined test signal to pass through a first delay circuit formed of a gate array having a predetermined number of stages for allowing aging degradation to progress and a delay of a second output signal obtained by allowing the test signal to pass through a second delay circuit formed of a gate array having the same number of stages as the first delay circuit, the test signal being allowed to pass through the second delay circuit after varying a delay period involved in the second delay circuit by a predetermined amount in an arbitrary delay step; repeating, in an adjustment step, based on comparison information output in the delay comparison step, the comparing while sequentially switching over the delay period of the second delay circuit determined in the arbitrary delay step; enabling identification of the delay period determined in the arbitrary delay step when the delay of the first output signal and the delay of the second output signal become equal to each other in the delay comparison step; and identifying degradation of the semiconductor integrated circuit based on the delay period determined when the delay of the first output signal and the delay of the second output signal become equal to each other, which is identified in the arbitrary delay step.

### Effect of the Invention

According to this invention, when the aging degradation diagnosis of a semiconductor integrated circuit is performed, measurement can be performed in a short period of time with a simple circuit configuration and without being affected by measurement environments.

### BRIEF DESCRIPTION OF THE DRAWINGS

FIG. 1 is a block diagram illustrating a configuration of an aging degradation diagnosis circuit according to a first embodiment of this invention.

FIG. 2 is a block diagram illustrating a configuration of an aging degradation diagnosis circuit according to a second embodiment of this invention.

FIG. 3 is a block diagram illustrating a configuration of an aging degradation diagnosis circuit according to a first example of this invention.

FIG. 4 is a block diagram illustrating a configuration of an aging degradation diagnosis circuit according to a second example of this invention.

### EMBODIMENTS FOR CARRYING OUT THE INVENTION

Next, embodiments of this invention will be described with reference to the drawings.

An aging degradation diagnosis circuit according to the embodiments of this invention includes two delay lines, a reference delay line and a test delay line, and includes a comparison unit for comparing outputs of the two delay lines. In the aging degradation diagnosis circuit, a signal passing through the reference delay line is arbitrarily delayed, and a length difference between a delay period of the reference delay line and a delay period of the test delay line is determined by the comparison unit. In accordance with the result of determination, a delay period to be provided to the reference delay line is automatically switched over, and the determination is made again. The aging degradation diagnosis circuit repeats the switch-over of the delay period and the determination. The aging degradation diagnosis circuit calculates a value (delay amount) at which the delay period involved in a signal passing through the test delay line and the delay period involved in the signal passing through the reference delay line become equal to each other, and estimates the degree of degradation based on the value (delay amount).

In this case, only the test delay line is degraded under an arbitrary condition, to thereby estimate the degree of progress of degradation in a semiconductor chip. Examples of the arbitrary condition for degradation include conditions of applying a voltage, a clock, and temperature under the same conditions as those of an actual circuit (main circuit, primary functional circuit). Alternatively, as an accelerated test, the condition of applying a higher stress than that of an actual circuit can also be used.

### First Embodiment

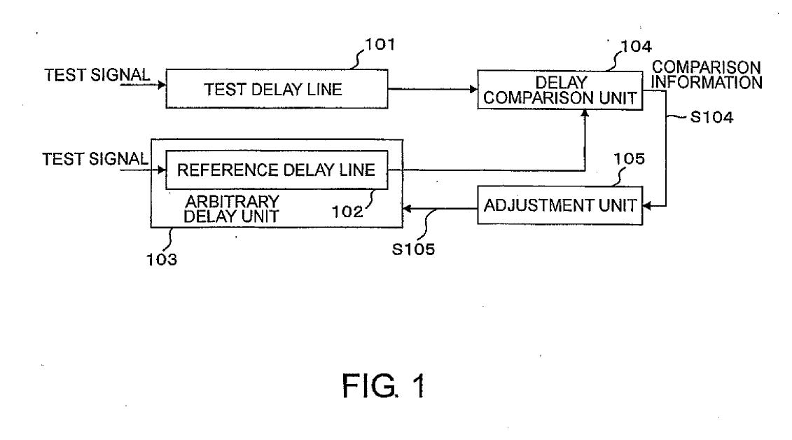

FIG. 1 is a block diagram illustrating a configuration of an aging degradation diagnosis circuit according to a first embodiment of this invention.

As illustrated in FIG. 1, the aging degradation diagnosis circuit (hereinafter, sometimes abbreviated as diagnosis circuit) according to the first embodiment is mounted on a semiconductor integrated circuit, and includes a test delay line (first delay circuit) 101, a reference delay line (second delay circuit) 102, an arbitrary delay unit 103, a delay comparison unit 104, and an adjustment unit 105.

The test delay line 101 and the reference delay line 102 are each configured to output an input signal after providing a predetermined delay to the input signal. The test delay line 101 and the reference delay line 102 are desired to have the same configuration. Note that, delays in the two delay lines are affected by similar effects depending on environments such as temperature and operating voltage.

The test delay line 101 and the reference delay line 102 each have a standby mode and a measurement mode.

In the standby mode, a stress is applied to the test delay line 101, that is, the degradation of the test delay line 101 is allowed to progress, and, on the other hand, no stress is applied to the reference delay line 102, for example, a power supply terminal is connected to GND so as to prevent the degradation. In this case, it is desired to allow the degradation to progress by using a trunk clock signal or the like in order to simulate the progress of degradation in a circuit that is actually operated (actual circuit) other than the diagnosis circuit.

In the measurement mode, on the other hand, the same test signals are input, and hence the two delay lines can start the measurement at the same time.

The arbitrary delay unit 103 is capable of generating a delay period at an arbitrary ratio relative to a delay period involved in the reference delay line 102. The delay period to be generated can be set arbitrarily to a predetermined value based on an input control signal. That is, an output signal having an arbitrary delay period can be produced by the reference delay line 102 and the arbitrary delay unit 103. Note that, the arbitrary delay unit 103 may be implemented by being connected in series or in parallel to the reference delay line 102 or by a combination thereof.

The delay comparison unit 104 receives the output signal of the test delay line 101 and the output signal of the reference delay line 102, compares the arrival timings of those two output signals, and outputs the result as comparison information S104. The comparison information S104 contains information indicating the difference in arrival timing and information indicating which of the two output signals has arrived earlier, for example, the logic level indicating the sign of the difference.

The adjustment unit 105 receives the comparison information S104 from the delay comparison unit 104, and adjusts the delay period of the arbitrary delay unit 103 to a delay period that is generated due to the degradation of the test delay line 101. That is, the adjustment unit 105 repeats the operation of adjusting the delay amount of the arbitrary delay unit 103 based on the comparison information 5104 from the delay comparison unit 104, until the delay period of the arbitrary delay unit 103 becomes equal to the delay period that is generated due to the degradation of the test delay line 101.

As described above, in the aging degradation diagnosis circuit according to the first embodiment, the delay comparison unit 104 derives a delay period that is increased by the degradation of the test delay line 101 by comparing the output signal of the test delay line 101 with the output signal of the reference delay line 102 that is output after repeatedly adjusting the delay period based on a control signal S105 supplied to the arbitrary delay unit 103. The delay comparison unit 104 then acquires information to be used for diagnosis of an actual circuit from a set value of the delay period that is set with respect to the arbitrary delay unit 103, the set value being the derived value. In other words, the degradation of the test delay line 101 can be extracted as the set value (delay period) of the arbitrary delay unit 103. The information relating to the set value is used appropriately by a degradation determination unit for an actual circuit or another circuit mounted together with a semiconductor integrated circuit.

The first embodiment employs a method of performing measurement a plurality of times while shifting the timing of the reference delay line, and can therefore realize a reduction in time period for measurement of the aging degradation. The reason is that, unlike an existing diagnosis method, it becomes unnecessary to configure a long delay line for measuring a minute change in degradation to measure a delay period of the delay line. In other words, both the reduction in circuit scale and the reduction in measurement time period can be attained.

Further, the ratio of the delay periods of the delay lines is obtained under the state in which the timing is consistent from the start to the end of the measurement. Accordingly, even under environmental fluctuations (such as power supply voltage and temperature), the denominator and the numerator of the ratio are affected similarly, and hence the environmental fluctuations are canceled in the course of the calculation. That is, degradation measurement free from the influence of environmental fluctuations can be performed.

Still further, a special analog circuit or the like is also unnecessary, and hence the aging degradation diagnosis circuit can be realized by a simple circuit configuration.

Next, a second embodiment of this invention will be described. In the second embodiment, parts different from the first embodiment are mainly described, and description of the same part is omitted.

### Second Embodiment

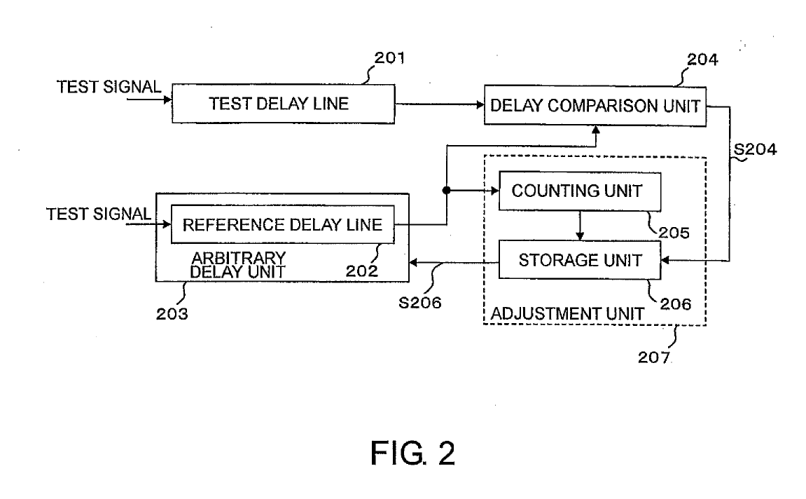

FIG. 2 is a block diagram illustrating a configuration of an aging degradation diagnosis circuit according to the second embodiment of this invention.

As illustrated in FIG. 2, the aging degradation diagnosis circuit according to the second embodiment includes an adjustment unit 207 formed of a counting unit 205 and a storage unit 206, instead of the adjustment unit 105 of FIG. 1. The counting unit 205 counts the number of outputs of the output signal from a reference delay line 202, and sends the count value to the storage unit 206. The storage unit 206 outputs, in accordance with the count value received from the counting unit 205, a control signal S206 for generating a delay amount (delay period) that is set and previously registered in association with the count value. As the delay amount set and previously registered in the storage unit 206, desired ranges (delay periods) for degradation detection are allocated at a desired resolution. The storage unit 206 stores the delay amount in association with the count value of the counting unit 205.

In the aging degradation diagnosis circuit, every time the output signal from the reference delay line 202 is output, the count value to be output from the counting unit 205 increases, and the control signal S206 for generating the delay amount which is stored in the storage unit 206 in association with the count value is supplied to an arbitrary delay unit 203. In this case, a delay comparison unit 204 may output a result 5204 of comparing the delay amount of the output signal of a test delay line 201 with the delay amount of the output signal of the reference delay line 202 (difference in delay amount or magnitude relationship of the delay amounts) to the storage unit 206 so as to set the control signal S206 to be output from the storage unit 206.

In this way, the configuration formed of the counting unit and the storage unit is used as the adjustment unit, and hence the aging degradation diagnosis circuit can be formed with a simple configuration, and, when the aging degradation diagnosis is performed on a semiconductor integrated circuit, the measurement can be performed in a short period of time without being affected by measurement environments.

### First Example

Next, a first example of this invention is described.

In the first example, the configuration according to the second embodiment illustrated in FIG. 2 is exemplified. That is, the aging degradation diagnosis circuit includes the test delay line 201, the reference delay line 202, the arbitrary delay unit 203, the delay comparison unit 204, the counting unit 205, and the storage unit 206. Note that, in the first example, elements for which no explanation is needed and overlapping descriptions are omitted as appropriate. It should also be understood that the first example is not limited as the only structure for achieving the object of this invention.

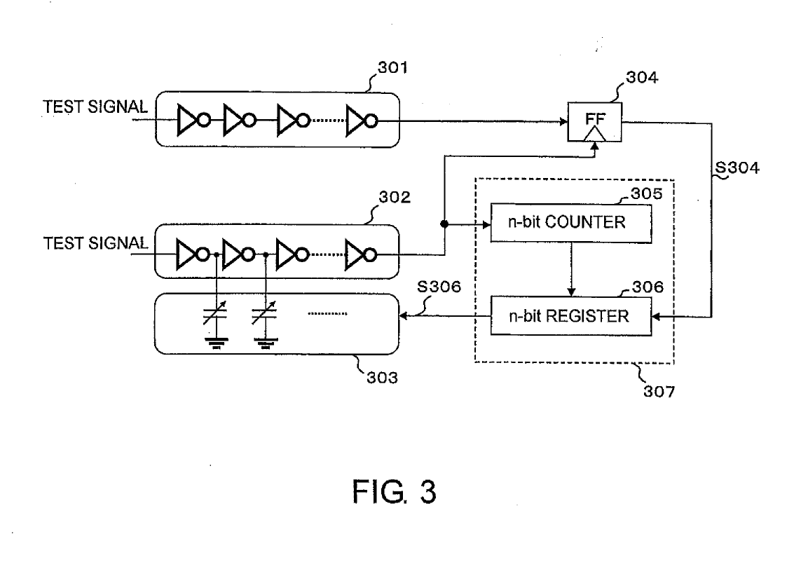

In the first example, as illustrated in FIG. 3, a test delay line 301 and a reference delay line 302 are each formed of a logic gate array, and in this case, NOT circuits are used. The test delay line 301 and the reference delay line 302 are formed of the same number of inverters, and delay periods to be generated are equal in an initial state (at the time of manufacturing). The test delay line 301 can be subjected to degradation under an arbitrary degradation environment (such as an environment simulating degradation of an actual circuit).

An arbitrary delay unit 303 can be implemented by connecting capacitive elements between the logic gate stages of the reference delay line 302. The capacitive elements having different capacitance values are provided in advance so as to be connectable to respective nodes of the logic gate stages, and the connections of ON/OFF are controllable by a control signal S306 so as to generate an arbitrary delay amount. Note that, an arbitrary delay amount may be generated by changing the capacitance value of each capacitive element in accordance with the control signal input to the arbitrary delay unit 303. The capacitive element group to be used may be formed in a semiconductor integrated circuit or may be connected from the outside.

A delay comparison unit 304 can be implemented by a flip-flop circuit, for example. The delay comparison unit 304 latches an output state of the test delay line 301 at output timing of the reference delay line 302. Thus, the delay comparison unit 304 can output comparison information S304 indicating which of the signals has arrived earlier.

An adjustment unit 307 is formed of a counting unit 305 and a storage unit 306. The storage unit 306 can be implemented by using a multi-bit (n-bit) register, for example. Based on the register value, the adjustment unit 307 selects the control signal S306 for adjusting a delay period to be generated by the arbitrary delay unit 303. The counting unit 305, which can be implemented by an n-bit counter, acquires the output of the reference delay line 302 to count the number of measurements. The count value is used for the selection of the control signal S306 to be output by the storage unit 306.

According to this configuration, the delay comparison unit 304 compares a delay period containing an increment resulting from the degradation of the test delay line 301 with the output signal of the reference delay line 302 set by the arbitrary delay unit 303, and the counting unit 305 counts the number of comparisons (the number of measurements). Then, information in the storage unit 306 is reset in accordance with the number of comparisons and the comparison result (comparison information). In this way, the delay period of the arbitrary delay unit 303 is automatically adjusted, and, by repeating the comparison, the counting, the resetting, and the delay period adjustment again, a final delay amount (delay period) of the arbitrary delay unit 303 is determined. Based on the finally determined delay amount, for example, a digital signal processor (DSP) or the like provided in an actual circuit identifies (estimates) the degradation of a semiconductor integrated circuit. The search for a point at which the delay differences of the two delay lines are matched can be performed in such a manner that the delay amounts previously set in the storage unit 306 are sequentially tested in ascending or descending order and the set delay amount corresponding to the inversion of the logic level of the output signal (comparison information) from the delay comparison unit 304 is determined as the delay amount resulting from the degradation of the test delay line 301. According to this measurement, the test can be suspended upon the detection of the inversion of the output from the delay comparison unit 304, and hence the search speed can be increased. In addition, the measurement may be started from an intermediate value of the measurement range to identify which of the output signals output from the delay lines has arrived at the delay comparison unit 304 earlier, and it may be selected whether to set the delay amounts in descending order or ascending order so that the delay difference may be reduced with respect to the intermediate value. In this case, the measurement range can be halved.

This measurement is relative timing comparison between the two delay lines. Therefore, measurement free from the influence of measurement environments (such as power supply voltage and temperature) can be realized.

Further, the register as the storage unit 306 only needs to have the bit numbers satisfying the range and resolution for delays to be measured, and hence the circuit scale can be significantly reduced.

### Second Example

Next, a second example of this invention will be described.

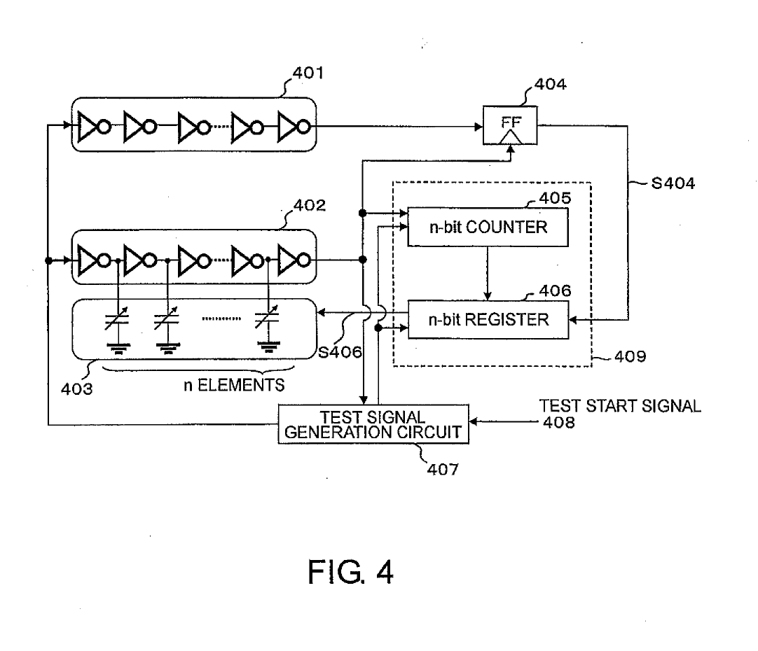

As illustrated in FIG. 4, an aging degradation diagnosis circuit according to the second example has, in addition to a test delay line 401, a reference delay line 402, an arbitrary delay unit 403, a delay comparison unit 404, and an adjustment unit 409 formed of a counting unit 405 and a storage unit 406, a test signal generation circuit 407 mounted thereon.

As illustrated in FIG. 4, the test delay line 401 and the reference delay line 402 are formed of the same number of gates and stages, and delay periods to be generated are equal in an initial state. Degradation of the test delay line 401 is allowed to progress under an arbitrary degradation environment.

The arbitrary delay unit 403 can be implemented by connecting capacitive elements between the logic gate stages of the reference delay line 402. The capacitive elements having different capacitance values are provided in advance so as to be connectable to respective nodes of the logic gate stages, and the connections of ON/OFF are controllable by a control signal S406 so as to generate an arbitrary delay amount. It should be understood that an arbitrary delay amount may be generated by changing the capacitance value of each capacitive element in accordance with the control signal input to the arbitrary delay unit 403. The capacitive element group to be used may be formed in a semiconductor integrated circuit or may be connected from the outside.

The delay comparison unit 404 is implemented by a flip-flop circuit. The delay comparison unit 404 samples an output state of the test delay line 401 at output timing of the reference delay line 402. Thus, the delay comparison unit 404 outputs comparison information 5404 indicating which of the signals has arrived earlier in a form of a logic level.

The counting unit 405, which can be implemented by an n-bit counter, monitors the output of the reference delay line 402 to count the number of measurements. The counted number of measurements is used for the storage unit 406 to select a set value, together with the comparison information 5404 of the delay comparison unit 404.

The storage unit 406 is implemented by using a multi-bit register. The value to be stored in the storage unit 406 is determined in accordance with the comparison information 5404 from the delay comparison unit 404 indicating which of the output signals has arrived earlier and in accordance with the number of measurements from the counting unit 405. That is, the storage unit 406 receives the outputs of the delay comparison unit 404 and the counting unit 405 and sets and stores a new set value in each bit of the register. The set value stored at this time, namely the control signal S406, is used to control ON/OFF of the connection of each capacitive element in the arbitrary delay unit 403, to thereby adjust the delay period to be generated by the arbitrary delay unit 403.

The test signal generation circuit 407 switches, in accordance with an input test start signal 408, the operating modes of the test delay line 401 and the reference delay line 402 to a standby mode or a measurement mode. The test signal generation circuit 407 also initializes the counting unit 405 and the storage unit 406. The test signal generation circuit 407 further receives the output of the reference delay line 402 and switches the operating modes of the test delay line 401 and the reference delay line 402 between the standby mode and the measurement mode.

A specific measurement procedure according to the second example is as follows. It should be understood that examples of the set value and signals as used herein for description are not intended to be the only values to be set in the second example.

Now, a time period necessary for signal propagation of the test delay line 401 and the reference delay line 402 is represented by T. When aging degradation is caused under an arbitrary stress condition, the time period necessary for signal propagation of the test delay line 401 becomes T+ΔT. Delay periods that can be generated by the arbitrary delay unit 403 are seven kinds of delay periods of 0.1%, 0.2%, 0.4%, 0.8%, 1.6%, 3.2%, and 6.4% relative to T. Those delay periods can be selected independently, and a plurality of delay ratios can be selected arbitrarily. Note that, respective delay elements are delay amounts obtained by discretizing, into predetermined numbers, a delay period ranging from a minimum delay period to a maximum delay period that enables measurement in correspondence with a binary sequence. In the example described above, the delay periods are provided in increments of 0.1% so that the minimum period is 0.1% and the maximum period is 12.7%, and 6.4% is set as the maximum delay element, to thereby vary the delay amount having an arbitrary ratio. In this case, the storage unit 406 includes a 7-bit register capable of setting the ON/OFF state of each of those set values. The counting unit 405 is also a counter capable of counting seven times or more. Further, in order to adjust the seven kinds of delay amounts, the reference delay line 402 and the arbitrary delay unit 403 are configured so that the above-mentioned seven kinds of delay elements (capacitive elements) are connected between eight inverters in correspondence with each bit digit of the register.

First, the test delay line 401 and the reference delay line 402 are set to the standby mode based on the test start signal 408 and the test signal generation circuit 407. This is realized by, for example, causing the test signal generation circuit 407 to generate a Low (L) level signal and input the Low (L) level signal to the test delay line 401 and the reference delay line 402. As initial processing in response to the test start signal 408, the test signal generation circuit 407 clears the counting unit 405. In the storage unit 406, only the value of the bit digit corresponding to the delay amount of 6.4%, which is the maximum delay element, is set to be ON, and the values of the remaining bit digits are all set to be OFF. In accordance with the set value of the storage unit 406, the arbitrary delay unit 403 provides the delay of 6.4% to the reference delay line 402.

Next, after a sufficient time period has elapsed or upon detection of the output of the reference delay line 402, the test signal generation circuit 407 generates a signal for switching the test delay line 401 and the reference delay line 402 to the measurement mode. This is realized by, for example, causing the test signal generation circuit 407 to generate a signal that transitions from L level to High (H) level and input the signal to the test delay line 401 and the reference delay line 402. As a result, in the standby mode, the outputs of the logic gates of the test delay line 401 and the reference delay line 402 are sequentially inverted, starting from the input stage, by the input of H level from the test signal generation circuit 407. In this case, a time period necessary for signal propagation of the test delay line 401 is T+ΔT, and a time period necessary for signal propagation of the reference delay line 402 is T+6.4% T. The lengths of the time periods of T+ΔT and T+6.4% T are compared by the delay comparison unit 404.

An output 5404 of the delay comparison unit 404 represents a signal level of the test delay line 401 at the inversion timing of the output signal of the reference delay line 402. It is assumed that the output of the test delay line 401 in the standby mode is at H level and is inverted to L level after a sufficient time period has elapsed since the operating mode was set to the measurement mode. That is, the output of the delay comparison unit 404 becomes L level when T+ΔT<T+6.4% T is satisfied and H level when T+ΔT>T+6.4% T is satisfied. Further, the counting unit 405 increments the count by 1 in response to the inversion of the output of the reference delay line 402.

Now, it is assumed that the count of the counting unit 405 becomes 1 and the output of the delay comparison unit 404 becomes L level. This indicates T+ΔT<T+6.4% T, and hence ΔT<6.4% T is satisfied. Therefore, a set value is stored in the storage unit 406 so that, in the next measurement, the delay amount of 6.4% is changed to be OFF and, at the same time, the delay amount of 3.2% corresponding to the next maximum delay element is changed to be ON. Based on this set value, the delay amount to be generated by the arbitrary delay unit 403 is reset to 3.2%. In contrast, when considering the case where the output of the delay comparison unit 404 is at H level, ΔT>6.4% T is known, and hence a set value is stored in the storage unit 406 so that the delay of 3.2% is changed to be ON while the delay of 6.4% remains set to be ON. Based on this set value, the delay amount to be generated by the arbitrary delay unit 403 is reset to 6.4%+3.2%.

At the same time when the delay amount of the arbitrary delay unit 403 is reset, the test signal generation circuit 407 changes the operating modes of the test delay line 401 and the reference delay line 402 to the standby mode in response to the output of the reference delay line 402. Then, after a sufficient time period has elapsed or after the resetting by the arbitrary delay unit 403 has been finished, the standby mode of the test delay line 401 and the reference delay line 402 is changed to the measurement mode again. In response to this measurement, the count of the counting unit 405 becomes 2, and the output of the delay comparison unit 404 is obtained. The output 5404 of the delay comparison unit 404 at this time is used for determination of ON/OFF of the delay of 3.2% in the current measurement, though the output S404 was used for determination of ON/OFF of the delay of 6.4% in the first measurement. This can be easily realized by focusing on the change of the output of the counting unit 405 from 1 to 2. Similarly to the first measurement, after the determination of ON/OFF of the delay of 3.2%, the set value is reset so that the delay of 1.6% corresponding to the maximum delay element next to the determined delay element becomes ON. That is, the value to be reset in the case where the set value of the delay amount before measurement is 3.2% is 1.6% or 3.2%+1.6%. On the other hand, in the case where the set value of the delay amount before measurement is 6.4%+3.2%, the value to be reset is 6.4%+1.6% or 6.4%+3.2%+1.6%.

After the above-mentioned measurement is repeated, when the count value of the counting unit 405 reaches 7, ON/OFF of all the delay amounts of 0.1%, 0.2%, 0.4%, 0.8%, 1.6%, 3.2%, and 6.4% is determined, and ΔT is determined as any one of 0.1% T to 12.7% T in increments of 0.1%, or 0.1% T or less or 12.8% T or more.

According to this measurement, the maximum delay amount is set in the first measurement, and, after the next and subsequent measurements, the delay amount is reset to a half delay amount of the previous measurement and the measurement is repeated. Therefore, the delay amount can be made close to a true value with a smaller number of tests, and the circuit configuration can be simplified. The number of tests only needs to be the same as the bit numbers (digit numbers) of the storage unit capable of outputting the numbers that cover the resolution and the measurement range which are determined based on the requirements specification of an actual circuit. In other words, the delay period of the gate in the test delay line can be accurately identified by very short processing, and the degradation ratio of the gate can be estimated from the value thereof.

Further, the aging degradation diagnosis according to this invention is relative timing comparison between the two delay lines. Therefore, high-accurate measurement free from the influence of measurement environments (such as power supply voltage and temperature) can be realized.

As described above, the aging degradation diagnosis circuit to which this invention is applied is capable of realizing measurement in a short period of time with a simple circuit configuration and without being affected by measurement environments, when the aging degradation diagnosis of a semiconductor integrated circuit is performed.

Note that, specific configurations of this invention are not limited to the above-mentioned embodiments, and changes without departing from the gist of the invention are also included in this invention.

Further, part or whole of the above-mentioned embodiments can also be described as follows. Note that, the following notes are not intended to limit this invention.

### [Note 1]

An aging degradation diagnosis circuit for a semiconductor integrated circuit, including:

a first delay circuit including a gate array having a predetermined number of stages for allowing aging degradation to progress, the first delay circuit being configured to delay an input signal by a delay period involved in the gate array and output a first output signal;

a second delay circuit including a gate array having the same number of stages as the first delay circuit, the second delay circuit being configured to delay an input signal by a delay period involved in the gate array and output a second output signal;

an arbitrary delay unit, which is capable of varying the delay period in the second delay circuit by a predetermined amount;

a delay comparison unit, which receives the first output signal and the second output signal with respect to the same input signal to the first delay circuit and the second delay circuit, and outputs, as comparison information, a result of relatively comparing delays between the acquired first output signal and the acquired second output signal; and

an adjustment unit for controlling the arbitrary delay unit with use of the comparison information from the delay comparison unit, to thereby readjust the delay period in the second delay circuit.

### [Note 2]

An aging degradation diagnosis circuit for a semiconductor integrated circuit as described in Note 1, in which the adjustment unit includes a counting unit for counting a number of outputs of the second output signal, and sequentially readjust the delay period in the second delay circuit with use of a count value from the counting unit and the comparison information from the delay comparison unit.

### [Note 3]

An aging degradation diagnosis circuit for a semiconductor integrated circuit as described in Note 2, in which:

the delay comparison unit is formed of a flip-flop circuit, and outputs, as the comparison information, information indicating which of the first output signal and the second output signal has arrived earlier, in a form of a logic level; and

the adjustment unit sequentially readjusts the delay period in the second delay circuit with use of the count value from the counting unit and the comparison information from the delay comparison unit.

### [Note 4]

An aging degradation diagnosis circuit for a semiconductor integrated circuit as described in Note 3, in which:

the adjustment unit further includes a storage unit having a value for controlling the arbitrary delay unit previously stored therein; and

the storage unit outputs, as a control signal, the value for controlling the arbitrary delay unit based on the count value from the counting unit and the comparison information from the delay comparison unit, and a delay amount in the second delay circuit is sequentially readjusted by the control signal.

### [Note 5]

An aging degradation diagnosis circuit for a semiconductor integrated circuit as described in Note 4, in which:

the storage unit is an n-bit register, which stores delay amounts obtained by discretizing, into predetermined numbers, a delay period ranging from a minimum delay period to a maximum delay period that enables measurement in correspondence with a binary sequence; and

the storage unit sets a bit digit to be adjusted of the n-bit register based on the count value from the counting unit, and sets a value of the bit digit based on the comparison information from the delay comparison unit.

### [Note 6]

An aging degradation diagnosis circuit for a semiconductor integrated circuit as described in Note 5, in which the adjustment unit resets the delay amount to a delay amount which is half the previously set delay amount of the arbitrary delay unit, and repeats measurement.

### [Note 7]

An aging degradation diagnosis circuit for a semiconductor integrated circuit as described in Note 3, in which:

the adjustment unit includes a storage unit having a value for controlling the arbitrary delay unit previously stored therein;

the adjustment unit sequentially readjusts, as a delay amount in the second delay circuit, delay amounts previously set in the storage unit in accordance with the count value from the counting unit in ascending order or descending order; and

when the logic level of the comparison information from the delay comparison unit is inverted, degradation diagnosis is finished.

### [Note 8]

An aging degradation diagnosis circuit for a semiconductor integrated circuit as described in Note 7, in which the adjustment unit starts the measurement from an intermediate value of a measurement range, and, based on the comparison information from the delay comparison unit indicating which of the first output signal and the second output signal has arrived earlier in the form of the logic level, selects whether to set the delay amounts in descending order or ascending order so that a delay difference may be reduced with respect to the intermediate value.

### [Note 9]

An aging degradation diagnosis circuit for a semiconductor integrated circuit as described in Note 5, further including a test signal generation circuit for sequentially sending, in response to a test start signal for degradation diagnosis, the same test signals to the first delay circuit and the second delay circuit until a number of outputs of the test signals reaches a number corresponding to digit numbers of the n-bit register constituting the storage unit.

### [Note 10]

An aging degradation diagnosis circuit for a semiconductor integrated circuit, including:

a test delay line in which a predetermined number of inverters subjected to aging degradation progress are connected in series, the test delay line being configured to output an input signal after providing a certain delay to the input signal;

a reference delay line in which the same number of inverters as the test delay line are connected in series while aging degradation resulting from a signal input is stopped, the reference delay line being capable of adding a predetermined delay to an input signal;

an arbitrary delay unit capable of turning ON/OFF of connections of capacitive elements with respect to the reference delay line so as to set, with respect to the delay involved in the reference delay line, delay amounts obtained by discretizing, into predetermined numbers, a delay period ranging from a minimum delay period to a maximum delay period that enables measurement in correspondence with a binary sequence, to thereby vary a delay having an arbitrary ratio;

a comparison unit, which receives output signals of the test delay line and the reference delay line with respect to the same test signal input to the test delay line and the reference delay line as a first output signal and a second output signal, respectively, and outputs comparison information indicating a relative arrival order of the first output signal and the second output signal;

a counting unit, which receives the second output signal with respect to the test signal input to the reference delay line to count a number of receptions of the second output signal, and outputs the count value;

a storage unit, which receives the count value output from the counting unit and the comparison information from the comparison unit, and sets a digit of the binary sequence that is allocated in advance to the count value, namely a bit digit value, to be enabled or disabled, to thereby adjust a delay amount determined by the arbitrary delay unit; and

a test signal generation circuit for sending the test signal by numbers corresponding to digit numbers of the storage unit.

### [Note 11]

An aging degradation diagnosis circuit for a semiconductor integrated circuit as described in Note 10, in which the aging degradation diagnosis circuit is configured to:

when an instruction of measurement start of the delay period based on aging degradation is received by the test signal generation circuit, reset the counting unit, set the value of the storage unit so that a diagnosis digit becomes a maximum digit as an initial value, and set the delay amount to be set with respect to the arbitrary delay unit to a value that enables only a maximum digit number;

adjust the arbitrary delay unit based on the setting of the storage unit;

based on outputs of the test delay line and the reference delay line resulting from the input of the same test signal, set the value of the diagnosis digit of the storage unit to be enabled when the output of the reference delay line has arrived at the comparison unit earlier than the output of the test delay line, and set the value of the diagnosis digit of the storage unit to be disabled and shift the value to a diagnosis digit indicated by the counting unit when the output of the reference delay line has arrived at the comparison unit later than the output of the test delay line; and

repeat the above-mentioned operation by numbers necessary for finishing the setting of all the diagnosis digits.

### [Note 12]

A semiconductor integrated circuit, including the aging degradation diagnosis circuit as described in the above-mentioned Notes built therein,

in which a delay of a gate array, which is increased by allowing aging degradation to progress, is identified based on a set value of the arbitrary delay unit, to thereby identify degradation.

### [Note 13]

An aging degradation diagnosis method for a semiconductor integrated circuit, including:

relatively comparing, in a delay comparison step, a delay of a first output signal obtained by allowing a predetermined test signal to pass through a first delay circuit formed of a gate array having a predetermined number of stages for allowing aging degradation to progress and a delay of a second output signal obtained by allowing the test signal to pass through a second delay circuit formed of a gate array having the same number of stages as the first delay circuit, the test signal being allowed to pass through the second delay circuit after varying a delay period involved in the second delay circuit by a predetermined amount in an arbitrary delay step;

repeating, in an adjustment step, based on comparison information output in the delay comparison step, the comparing while sequentially switching over the delay period of the second delay circuit determined in the arbitrary delay step;

enabling identification of the delay period determined in the arbitrary delay step when the delay of the first output signal and the delay of the second output signal become equal to each other in the delay comparison step; and

identifying degradation of the semiconductor integrated circuit based on the delay period determined when the delay of the first output signal and the delay of the second output signal become equal to each other, which is identified in the arbitrary delay step.

### [Note 14]

An aging degradation diagnosis method for a semiconductor integrated circuit as described in Note 13, in which:

the delay comparison step is executed by a flip-flop circuit, which outputs, as the comparison information, information indicating which of the first output signal and the second output signal has arrived earlier;

the adjustment step is executed by an n-bit counter for counting an output of the test signal from the second delay circuit and an n-bit register having delay amounts previously stored therein, the delay amounts being obtained by discretizing, into predetermined numbers, a delay period ranging from a minimum delay period to a maximum delay period that enables measurement of an adjustment time period in the arbitrary delay step, in correspondence with a binary sequence; and

the arbitrary delay step includes setting a bit digit for adjusting a value of the n-bit register based on a count value from the n-bit counter, and setting whether to enable or disable a value of the bit digit based on a signal output from the flip-flop circuit.

### [Note 15]

An aging degradation diagnosis method as described in Note 14, in which the adjustment step includes setting, as an initial value, a bit digit of a maximum delay element to be enabled, executing setting of an adjacent bit digit having a delay amount which is half a delay amount of the previously set delay element based on the count value from the n-bit counter, and repeating an operation of the setting by n times in total.

### INDUSTRIAL APPLICABILITY

This invention is applicable to aging degradation diagnosis based on a delay in a semiconductor integrated circuit such as an LSI.

This invention is also applicable to the prevention of a failure as well as the estimation of a failure timing of a system and the diagnosis of the system, with the use of a delay amount acquired by this invention.

This application claims priority from Japanese Patent Application No. 2010-075292, filed on Mar. 29, 2010, the entire disclosure of which is incorporated herein by reference.

### REFERENCE SIGNS LIST

101, 201, 301, 401 test delay line
102, 202, 302, 402 reference delay line
103, 203, 303, 403 arbitrary delay unit
105 adjustment unit
205, 305, 405 counting unit
206, 306, 406 storage unit
407 test signal generation circuit
408 test start signal

1. An aging degradation diagnosis circuit for a semiconductor integrated circuit, comprising:
a first delay circuit including a gate array having a predetermined number of stages for allowing aging degradation to progress, the first delay circuit being configured to delay an input signal by a delay period involved in the gate array and output a first output signal;
a second delay circuit including a gate array having the same number of stages as the first delay circuit, the second delay circuit being configured to delay an input signal by a delay period involved in the gate array and output a second output signal;
an arbitrary delay unit, which is capable of varying the delay period in the second delay circuit by a predetermined amount;
a delay comparison unit, which receives the first output signal and the second output signal with respect to the same input signal to the first delay circuit and the second delay circuit, and outputs, as comparison information, a result of relatively comparing delays between the acquired first output signal and the acquired second output signal; and
an adjustment unit for controlling the arbitrary delay unit with use of the comparison information from the delay comparison unit, to thereby readjust the delay period in the second delay circuit.

2. An aging degradation diagnosis circuit for a semiconductor integrated circuit according to claim 1, wherein the adjustment unit comprises a counting unit for counting a number of outputs of the second output signal, and sequentially readjust the delay period in the second delay circuit with use of a count value from the counting unit and the comparison information from the delay comparison unit.

3. An aging degradation diagnosis circuit for a semiconductor integrated circuit according to claim 2, wherein:
the delay comparison unit is formed of a flip-flop circuit, and outputs, as the comparison information, information indicating which of the first output signal and the second output signal has arrived earlier, in a form of a logic level; and
the adjustment unit sequentially readjusts the delay period in the second delay circuit with use of the count value from the counting unit and the comparison information from the delay comparison unit.

4. An aging degradation diagnosis circuit for a semiconductor integrated circuit according to claim 3, wherein:
the adjustment unit further comprises a storage unit having a value for controlling the arbitrary delay unit previously stored therein; and
the storage unit outputs, as a control signal, the value for controlling the arbitrary delay unit based on the count value from the counting unit and the comparison information from the delay comparison unit, and a delay amount in the second delay circuit is sequentially readjusted by the control signal.

5. An aging degradation diagnosis circuit for a semiconductor integrated circuit according to claim 4, wherein:
the storage unit comprises an n-bit register, which stores delay amounts obtained by discretizing, into predetermined numbers, a delay period ranging from a minimum delay period to a maximum delay period that enables measurement in correspondence with a binary sequence; and
the storage unit sets a bit digit to be adjusted of the n-bit register based on the count value from the counting unit, and sets a value of the bit digit based on the comparison information from the delay comparison unit.

6. An aging degradation diagnosis circuit for a semiconductor integrated circuit according to claim 5, wherein the adjustment unit resets the delay amount to a delay amount which is half the previously set delay amount of the arbitrary delay unit, and repeats measurement.

7. An aging degradation diagnosis circuit for a semiconductor integrated circuit based on a delay according to claim 3, wherein:
the adjustment unit comprises a storage unit having a value for controlling the arbitrary delay unit previously stored therein;
the adjustment unit sequentially readjusts, as a delay amount in the second delay circuit, delay amounts previously set in the storage unit in accordance with the count value from the counting unit in ascending order or descending order; and
when the logic level of the comparison information from the delay comparison unit is inverted, degradation diagnosis is finished.

8. An aging degradation diagnosis circuit for a semiconductor integrated circuit according to claim 7, wherein the adjustment unit starts the measurement from an intermediate value of a measurement range, and, based on the comparison information from the delay comparison unit indicating which of the first output signal and the second output signal has arrived earlier in the form of the logic level, selects whether to set the delay amounts in descending order or ascending order so that a delay difference may be reduced with respect to the intermediate value.

9. An aging degradation diagnosis circuit for a semiconductor integrated circuit according to claim 5, further comprising a test signal generation circuit for sequentially sending, in response to a test start signal for degradation diagnosis, the same test signals to the first delay circuit and the second delay circuit until a number of outputs of the test signals reaches a number corresponding to digit numbers of the n-bit register constituting the storage unit.

10. An aging degradation diagnosis method for a semiconductor integrated circuit, comprising:
relatively comparing, in a delay comparison step, a delay of a first output signal obtained by allowing a predetermined test signal to pass through a first delay circuit formed of a gate array having a predetermined number of stages for allowing aging degradation to progress and a delay of a second output signal obtained by allowing the test signal to pass through a second delay circuit formed of a gate array having the same number of stages as the first delay circuit, the test signal being allowed to pass through the second delay circuit after varying a delay period involved in the second delay circuit by a predetermined amount in an arbitrary delay step;
repeating, in an adjustment step, based on comparison information output in the delay comparison step, the comparing while sequentially switching over the delay period of the second delay circuit determined in the arbitrary delay step;
enabling identification of the delay period determined in the arbitrary delay step when the delay of the first output signal and the delay of the second output signal become equal to each other in the delay comparison step; and
identifying degradation of the semiconductor integrated circuit based on the delay period determined when the delay of the first output signal and the delay of the second output signal become equal to each other, which is identified in the arbitrary delay step.
